(19) United States
(12) Patent Application Publication
(10) Pub. No.: US 2013/0277268 A1
(43) Pub. Date: Oct. 24, 2013

(54) FRONT OPENING WAFER CONTAINER WITH DOOR DEFLECTION MINIMIZATION

(71) Applicant: Matthew A. Fulller, Colorado Springs, CO (US)

(72) Inventor: Matthew A. Fulller, Colorado Springs, CO (US)

(73) Assignee: ENTEGRIS, INC., Billerica, MA (US)

(21) Appl. No.: 13/880,944

(22) PCT Filed: Oct. 19, 2011
(86) PCT No.: PCT/US11/56921

§ 371 Date: Jul. 8, 2013

Related U.S. Application Data
(60) Provisional application No. 61/394,770, filed on Oct. 20, 2010.

(51) Int. Cl. H01L 21/677

(52) U.S. Cl. CPC H01L 21/67772
USPC 206/710; 220/212

(57) ABSTRACT

A front opening wafer container suitable for 450 mm diameter wafers. The front door has a pair of latch mechanism externally operable on the sides of the door, each latching mechanism having a pair of latch tips extendible from top and bottom peripheries of the door into receivers in the door frame of the front opening of the container portion. The door contains wafer cushions that support horizontally stacked wafers. The cushions have vertically extending support strip regions with arcuate wafer engagement portions therebetween. The arcuate wafer engagement portion is positioned in a vertically extending central recess on the inside surface of the door. The wafer cushion is secured to the inside of the door at the pair of vertically extending support strip portions at a pair of vertically extending loading junctures. The latching tips of each latching mechanism is in a vertical alignment with the vertically extending loading junctures.

### RELATED APPLICATIONS

The present application is a National Phase entry of PCT Application No. PCT/US2011/056921, filed Oct. 19, 2011, which claims priority to U.S. Provisional Application Ser. No. 61/394,770, filed Oct. 20, 2010, the disclosures of which are hereby incorporated by reference herein in their entirety.

### BACKGROUND OF THE INVENTION

Integrated circuits such as computer chips are manufactured from silicon wafers. The silicon wafers need to be maintained in extremely clean and contamination free environments during their transport and in between manufacturing process steps. Additional, required or desirable characteristics of containers to transport and/or store semiconductor wafers include light weight, rigidity, cleanliness, limited gaseous emissions, and cost effective manufacturability. The containers provide hermetic or close to hermetic isolation of wafers when the containers are closed. Simply stated, such containers need to keep the wafers clean, uncontaminated, and undamaged.

Plastic containers have been used for decades for transporting and storing wafers in-between process steps. Selected polymer materials provide adequate characteristics. Such containers have highly controlled tolerances for interfacing with processing equipment as well as the equipment/robots that transport the containers. Moreover, it is desirable in such plastic containers to utilize components that are attachable and removable without using metallic fasteners such as screws. Metal fasteners cause particle generation when inserted and removed.

Driven by cost efficiencies and improved manufacturing capabilities, the size of wafers utilized in manufacturing semiconductors has been increasing. Now several fabrication facilities utilize 300 mm wafers. As the size of wafers has increased and the density of the circuits has increased making the circuits susceptible to smaller and smaller particles and other contaminants. Thus, as the wafers have increased in size, the containers have increased in size as well; the requirements of keeping the wafers clean and contaminant free have become more stringent due to the wafers being more susceptible to smaller particles and other contaminants, containers have increased in size. Additionally, carriers need to maintain their capabilities under the rigors of robotic handling which includes lifting the carrier by the robotic flange positioned at the top of the container.

Front opening wafer containers have become the industry standard for transporting and storing large diameter 300 mm wafers. In such wafer containers the front door is latchable to a container portion and closes a front access opening through which the wafers are robotically inserted and removed. When the container is fully loaded with wafers the door is inserted into the door frame of the container portion and latched thereto. When seated the cushions on the door then provide upward, downward, and inward constraint.

A problem discovered in fabricating front opening plastic containers for holding and/or transporting larger wafers, for example 300 mm containers, is that the expanses of plastic utilized on the top, bottom, sides, front, and back of the container may flex due to the increased weight of the wafer load when the container is lifted and the front door and back side may flex outwardly due to the retention of the wafers between wafer cushions on the front door and back side of the containers.

The semiconductor industry is now moving toward utilizing larger, 450 mm diameter wafers. The larger diameter wafers, although providing cost efficiencies, also provide increased fragility, greater weight, and present undiscovered issues associated with handling and storing the larger wafers in containers made of plastic. The flexing and corresponding problems associated with the expanses of plastic on the top, bottom, sides, front, and back are exacerbated.

With the significant leaps in the size of processed wafers, new issues and problems arise that were not present with smaller sized wafers. Many standards for 450 mm wafers, such as the number of wafers in containers and the spacing between wafers, may very well remain the same as 300 mm wafer container standards due to existing equipment compatibilities and cost pressures. And, of course, as wafers get larger in diameter, they correspondingly get heavier. A wafer container that holds the same number of 450 mm wafers as is provided in standardized 300 mm containers is expected to weigh approximately 40 pounds. At this weight, manual handling starts to become more difficult.

Using comparable thicknesses of polymer walls for a larger container may not provide sufficient structural rigidity of the container. That is, the container would be expected to be less dimensionally stable under loading, transfer and shipping due to the greater dimensions and greater expanses of polymer. Thickening the walls and adding significant strengthening structure would further increase the weight of 450 mm wafer containers.

Moreover, conventional 300 mm wafer containers are typically injection molded. It is anticipated that it will be difficult to adequately control the dimensions of larger containers utilizing comparable injection molding practices and comparable or larger wall thicknesses. Currently 300 mm wafer containers generally utilize the shell as the principal structural member for positioning components that interface with wafers and outside equipment, namely the wafer supports and the kinematic coupling machine interface.

In addition, the open interior volume will significantly increase as will the area of the open front that sealingly receives the door. This suggests more difficult sealing issues between the door and the container portion.

Wafers of larger dimensions will also have significantly greater sag which will make them more susceptible to damage during handling and transport and require unique support not required for smaller wafers. This greater sag presents challenges in maintaining the desired spacing between wafers while still allowing placement and removal of the wafers robotically by robotic arms.

Accordingly, it would be desirable to develop front opening configurations for 450 mm wafer containers that have design attributes for minimizing wafer sag and minimizing weight of the container. In addition, configurations providing improved sealing characteristics for the doors would be desirable. Moreover, configurations providing enhanced wafer support to accommodate storing of 450 mm wafers in wafer containers as well during robotic handling of the wafers would be desirable.

### SUMMARY OF THE INVENTION

A front opening wafer container suitable for 450 mm has a container portion with a front opening and a front door that closes the front opening. The front door has a pair of latch mechanisms externally operable on each of the left side and right side of the door, each latching mechanism has a pair of latch tips extendible from the top periphery and bottom periphery of the door into receivers positioned in a door frame that defines the front opening of the container portion. A wafer cushion supports the front edges of horizontal wafers that are arranged in a spaced stacked arrangement. In an embodiment of the invention, the wafer cushion has a pair of vertically extending support strip regions with an arcuate wafer engagement portion extending horizontally therebetween. The arcuate wafer engagement portion being positioned in a vertically extending central recess on the inside surface of the door. The arcuate wafer engagement portion spaced from the inside surface of the front door. The wafer cushion is secured to the inside of the door at the pair of vertically extending support strip portions at a pair of vertically extending loading junctures where the load due to the compressive retention of the wafers between the wafer cushion and rear wafer supports is transferred between the wafer cushion to the front door. The robotic access key openings for the latching mechanisms are spaced horizontally outwardly from the vertically extending loading junctures. The latching tips of each respective latching mechanism is horizontally offset from the robotic access key openings and the latching tips are in alignment in a vertical line with the vertically extending loading junctures.

An issue heretobefore unrecognized is that the weight of the wafers engaged with the cushion on the front door can cause a considerable force component in the z direction causing distortion of the containers in the z direction primarily exhibited by an outward flexing of the door as well as the rear wall. In that the loading is provided from proximate the top edge of the door at the top wafer to the bottom edge of the door at the bottom wafer, and at the central part of the door, the force urges a bowing of door where the attachment points of the door to the doorframe are horizontally positioned outside the central force receiving region. It has been discovered that this force can cause door deflection issues that can affect the integrity of the seal between the door and door frame, particularly in the context of 450 mm wafer containers.

A feature and advantage of embodiments of the invention is that wafer retention forces are transferred directly to the door and do not traverse lateral through the door.

A feature and advantage of embodiments of the invention is that the door latch is in line with wafer retention attachment. This results in minimal deflection of the door.

A further advantage and feature of the invention is that since the loading of the door by the wafers extends down a central vertical region and is essentially uniform from one horizontal datum level to the next, and since the door to door frame latches are typically at the top and bottom portions of the door frame, minimal in any bowing of the door about a horizontal (x direction) axis is induced in the door. Thus, by removing the bowing component with respect to any bowing about a vertical (y direction) axis, the integrity and consistency of the door to door frame seal in larger diameter wafer containers, particularly 450 mm containers, can be improved.

In an embodiment of the invention, vertically extending wafer load carrying junctures between the wafer cushions and front door structure are substantially in vertical alignment with the latch mechanism engagements with the door frame.

In an embodiment of the invention, the central recess on the inside surface of the front door has at least two depth levels, the deepest of the at least two depth levels being centrally positioned in the recess. A lesser depth level being position at the margins of the recess and have the wafer cushion attachment or wafer load carrying location of the wafer cushions on the door. The second level at a lesser depth allows the door mechanism to be in the door housing directly in front of said wafer attachment location or the load carrying location of the wafer cushions on the door. The pressure of this recess, which is common on 300 mm wafer containers, and is likely to be on many 450 mm container's doors makes the door features more susceptible to bowing than in doors of constant thickness, without central recesses.

Another embodiment of the invention is directed to a front opening wafer container. The wafer container includes a container portion having an interior with opposing columns of shelves sized for holding 450 mm wafers positioned in the interior at opposing sides of the container and a door frame defining a front opening. The wafer container also includes a door that operably closes the front opening of the container portion. The door includes a pair of latch mechanisms each externally operable at the sides of the door, each latch mechanism having a pair of latch tips extendible from the top periphery and bottom periphery of the door into receivers positioned in the door frame. The door also includes a wafer cushion, for supporting the front edges of horizontal wafers arranged in a spaced stacked arrangement, having a pair of vertically extending support strip portions with an arcuate wafer engagement portion extending horizontally therebetween, the arcuate wafer engagement portion being positioned in a vertically extending central recess on the inside surface of the door and spaced from the inside surface of the front door, the wafer cushions secured to the inside of the door at the pair of vertically extending support strip portions at a pair of vertically extending loading junctures where the load due to compressive retention of the wafers between the wafer cushion and rear wafer supports of the container portion is transferred between the wafer cushion to the front door. The door also includes a plurality of robotic access key openings for the latch mechanisms spaced horizontally outwardly from the vertically extending loading junctures, the latching tips of each respective latching mechanism horizontally offset from the robotic access key openings and the latching tips disposed in alignment in a vertical line with the vertically extending loading junctures. The wafers may be 450 mm diameter wafers.

Other embodiments of the invention are directed to a wafer container sized for 450 mm wafers that includes a container portion with a front opening, a front door, and a wafer cushion. The front door sized to fit in the front opening and equipped with two latch mechanisms having latching members adapted to operably extend from the top periphery and bottom periphery of the door. The wafer cushion is supported by the front door at positions in vertical alignment with the latching members of the two latch mechanisms.

An embodiment of the invention includes a front door for a front opening wafer container. The front door includes a front door structure with latch mechanisms adapted to operably extend from the top and bottom periphery of the front door structure to provide latch mechanism engagements with the door frame of a front opening wafer container. The front door also includes a wafer cushion having vertically extending wafer load carrying junctures between the wafer cushion and front door structure that are substantially in vertical alignment with the latch mechanism engagements.

Further embodiments of the invention relate to a front door for a front opening wafer container. The front door including a door housing with a central recess on the inside surface of the front door, the recess having at least two depth levels. A first deeper depth level of the at least two depth levels is centrally positioned in the recess. A second lesser depth level of the at least two depth levels being positioned at the margins of the recess and have a wafer cushion attachment or wafer load carrying location of the wafer cushions on the door. In this embodiment, the second lesser depth level allows door mechanisms to be in the door housing directly in front of the wafer cushion attachment location or the load carrying location of the wafer cushions on the front door.

Another embodiment includes a front door for a front opening wafer container. The front door includes a door housing, a wafer cushion, and a plurality of wafer latch tabs. The wafer cushion on the inside surface of the door housing adapted to carry horizontally stacked wafers. The plurality of wafer latch tabs are in vertical alignment with the portion of the wafer cushion on the inside surface of the door housing that carry the load from engaging the wafers.

Other embodiments include methods for minimizing door deflection in a front opening wafer container. Such methods include providing a wafer container, providing a front door for the wafer container, having a set of inwardly disposed wafer support cushions supported by the door by vertical support members, and deploying a set of latch mechanisms from locations in vertical alignment with the support members to hold the front door within the wafer container.

### DESCRIPTION OF THE DRAWINGS

FIG. 1 is a perspective of a front opening wafer container according to the invention.

FIG. 2 is a perspective view of the inside surface of a front door according to the invention herein.

FIG. 3 is a perspective view of another inside surface of a front door in accord with the invention herein.

FIG. 4 is a perspective view of another inside surface of a front door in accord with the invention herein.

FIG. 5 is a cross sectional view of a front door on a container portion illustrating the positioning of the wafer cushion and the latch tips.

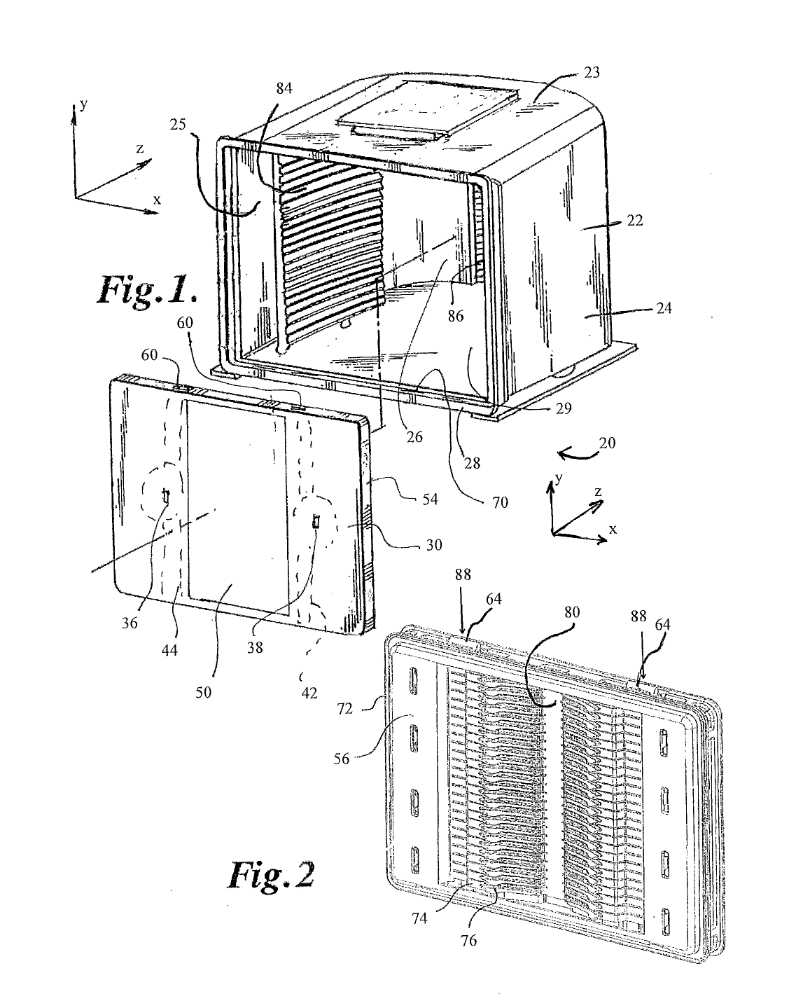

### DETAILED DESCRIPTION

Referring to the figures, a front opening wafer container 20 is illustrated and comprises generally a container portion 22, having a top wall 23, a pair of side walls 24, 25, a back wall 26, a door frame 28 defining a front opening 29, and a front door 30 configured to close the open front. The door has a pair of key holes 36, 38 that access latch mechanisms 42 located inside the door housing 44. Such latch mechanisms can be generally configured as illustrated in U.S. Pat. Nos. 4,995,430; 7,182,203; or 7,168,587, all of which are owned by the owner of the instant application, and all are incorporated herein by reference. The door has an outside surface 50, a periphery 54, and an inside surface 56. Slots 60 are positioned on the periphery and allow latching tabs 64 or tips to extend and retract from the door to engage and disengage recesses 70 on the inside surface of the door frame. A seal or gasket 72 follows the circumference of the door and engages with the door frame to sealingly close the door when the latches are actuated. Wafer cushion 74, comprising a plurality of wafer engaging portions 76 are positioned on the inside surface of the front door in a recess 80 that extends from the top of the door to the bottom of the door and is centrally position respect to the left and right sides of the door.

The container portion 22 has wafer supports in the form of shelves 84 at the interior sides of the container portion and also supports 86 in the rear that may be configures as cushions or as rigid supports with V-shaped (rotated 90 degrees) grooves for engaging the rear edge of wafers. The wafers may be elevated as the door in installed and latched in place. This is likely to be adopted in the 450 mm arena. The action of the elevation of the wafers is illustrated in U.S. Pat. No. 6,267,245, owned by the owner of the instant invention and incorporated herein by reference. The wafers are compressed between the wafer cushions on the inside surface of the door and the wafer supports at the rear of the container portion.

As illustrated best in FIGS. 2, 3, 4, and 5, the wafer latch tips or tabs 64 are in vertical alignment, with the portion of the wafer cushions on the inside surface of the front door that carry the load from engaging the wafers, that is compressing the wafers between said front cushion and the rear wafer supports. Said alignment precludes a bending moment being imparted to the door which, particularly in the expanses associated with 450 mm wafers, can create sealing problems with the door as well as issues in maintaining the secure constraints of the wafers when the container is closed. A latching mechanism that provides an offset of the latch tips from the key hole or center of the rotary wheel that conventionally drives such latching mechanisms, is illustrated in U.S. Pat. No. 7,182,203, previously incorporated by reference.

In each of FIGS. 2-5, the door latches can be seen to be in line with the wafer retention attachment in locations around the top and bottom periphery of the front door 30 at locations 88. A cross-sectional view of the arrangement, including a 450 mm wafer 99 is shown in FIG. 5. As seen in FIG. 5, wafer retention forces (F) exerted by the wafer cushion 74 are transferred directly to the latches 64. In this arrangement, little or no bending moment can be exerted on the door 30 to cause outward flexing of the door. Accordingly, deflection is minimized when wafer retention forces are not offset from the latches 64. The arrangement of the vertically extending support strip portions 90 and arcuate wafer engagement portions 92 of the wafer cushion 74 can be better understood from FIGS. 2-5. Further, the securing of the vertically extending support strip portions 90 at the pair of vertically extending loading junctures 94 is illustrated in the cross-section of FIG. 5 as well.

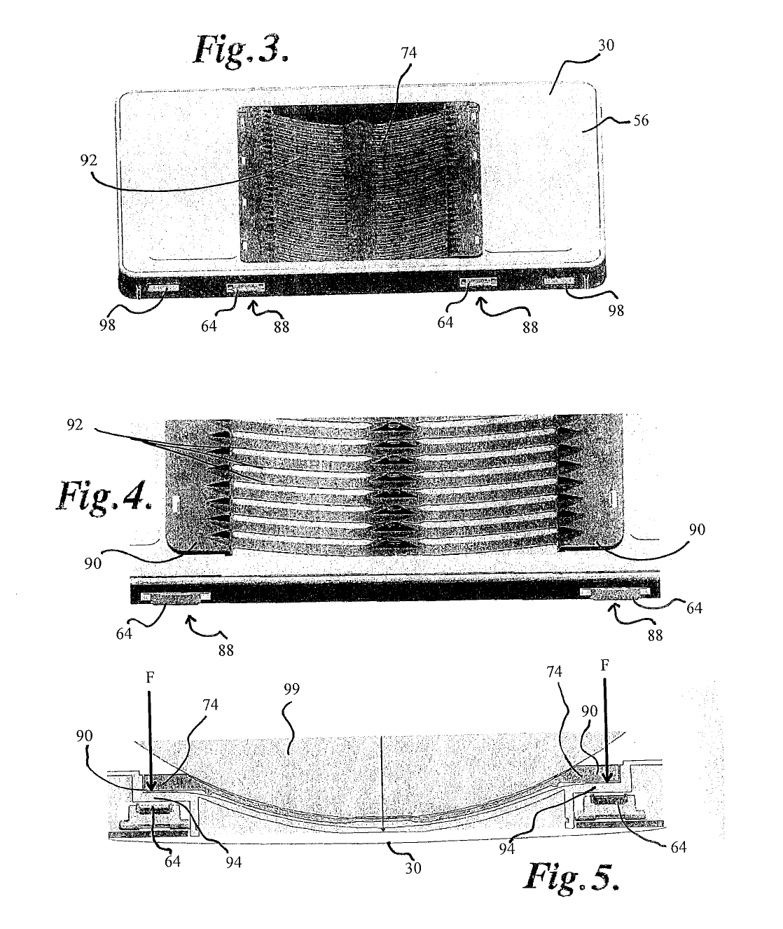

Additional secondary latch structure 98 can further be seen in FIG. 3. The secondary latches 98, may be further included near the corners of the top and bottom of the periphery of front door 30. These secondary latch structures 98 can be extend outwardly, similar to the operation of latching tabs 64, and can accordingly provide further securing the corners of the door 30 to the container 22.

For the various embodiments discussed throughout this application, the various wafer container components may generally be injected molded from polymers typically used for semiconductor wafers. For example, polycarbonates, fluoropolymers, polyetheretherketone.

It should also be appreciated that the exemplary embodiment or exemplary embodiments are only examples, and are not intended to limit the scope, applicability, or configuration of the invention in any way. Rather, the foregoing detailed description will provide those skilled in the art with an enabling disclosure for implementing the exemplary embodiment or exemplary embodiments. It should be understood that various changes can be made in the function and arrangement of elements without departing from the scope of the invention as set forth in the appended claims and the legal equivalents thereof.

The embodiments above are intended to be illustrative and not limiting. Additional embodiments are within the claims. Although the present invention has been described with reference to particular embodiments, workers skilled in the art will recognize that changes may be made in form and detail without departing from the spirit and scope of the invention.

Various modifications to the invention may be apparent to one of skill in the art upon reading this disclosure. For example, persons of ordinary skill in the relevant art will recognize that the various features described for the different embodiments of the invention can be suitably combined, un-combined, and re-combined with other features, alone, or in different combinations, within the spirit of the invention. Likewise, the various features described above should all be regarded as example embodiments, rather than limitations to the scope or spirit of the invention. Therefore, the above is not contemplated to limit the scope of the present invention.

1-5. (canceled)

6. A wafer container, comprising:
a container portion sized for 450 mm wafers with a front opening;
a front door sized to fit in the front opening and equipped with two latch mechanisms having latching members adapted to operably extend from the top periphery and bottom periphery of the door; and
a unitary wafer cushion that is spanning between and supported by the front door at positions in vertical alignment with the latching members of the two latch mechanisms, the positions of the front door carrying loading of the wafers when the front door is latched into the front opening.

7. The wafer container of claim 6, wherein the wafer cushion includes a pair of vertically extending support strip portions attached to the door in alignment with the latch members with an arcuate wafer engagement portion extending therebetween.

8. The wafer container of claim 7, wherein the arcuate wafer engagement portion is positioned in a vertically extending central recess of a depth on the inside surface of the front door and the vertically extending support strip portions are support at a lesser depth.

9. The wafer container of claim 7, wherein the wafer cushions are secured to the inside of the door at the pair of vertically extending support strip portions at a pair of vertically extending loading junctures.

10. The wafer container of claim 6, wherein the front door contains a plurality of robotic key openings for operating the two latch mechanisms.

11. The wafer container of claim 6, wherein the wafer container is made of one or more of: polycarbonates, fluoropolymers, and polyetheretherketone.

12. The wafer container of claim 6, wherein a secondary latch is used to further secure the corners of the door to the wafer container.

13. A front door for a front opening wafer container, comprising:
a front door structure with latch mechanisms adapted to operably extend from the top and bottom periphery of the front door structure to provide latch mechanism
engagements with the door frame of a front opening wafer container; and
a wafer cushion having vertically extending wafer load carrying junctures between the wafer cushion and front door structure that are substantially in vertical alignment with the latch mechanism engagements.

14. The front door of claim 13, wherein the wafer cushion includes a pair of vertically extending support strip portions with an arcuate wafer engagement portion extending therebetween.

15. The front door of claim 14, wherein the wafer cushions are secured to the inside of the front door at the pair of vertically extending support strip portions at the vertically extending wafer load carrying junctures.

16. The front door of claim 15, wherein the arcuate wafer engagement portion is positioned in a vertically extending central recess on the inside surface of the front door.

17. The front door of claim 13, wherein the front door contains a plurality of robotic key openings for operating the latch mechanisms.

18. The front door of claim 13, wherein a secondary latch is used to further secure the corners of the door to the wafer container.

19. A front door for a front opening wafer container, comprising:
a door housing with a central recess on the inside surface of the front door, the recess having at least two depth levels, including:
a first deeper depth level of the at least two depth levels being centrally positioned in the recess; and
a second lesser depth level of the at least two depth levels being positioned at the margins of the recess and have a wafer cushion attachment or wafer load carrying location of the wafer cushions on the door, wherein the second lesser depth level allows door mechanisms to be in the door housing directly in front of the wafer cushion attachment location or the load carrying location of the wafer cushions on the front door.

20. (canceled)

21. The front door of claim 19, wherein the wafer cushion includes a pair of vertically extending support strip portions with an arcuate wafer engagement portion extending therebetween.

22. The front door of claim 21, wherein the wafer cushions are secured to the inside of the front door at the pair of vertically extending support strip portions at the vertically extending wafer load carrying junctures.

23. (canceled)

24. The front door of claim 19, wherein the front door is made of one or more of: polycarbonates, fluoropolymers, and polyetheretherketone.

25. (canceled)
